(19) United States
(12) Patent Application Publication
(10) Pub. No.: US 2022/0380547 A1
(43) Pub. Date: Dec. 1, 2022

(54) THERMAL INTERFACE MATERIALS AND METHODS FOR APPLICATION

(71) Applicant: Henkel AG & Co. KGaA, Duesseldorf (DE)

(72) Inventors: Ryan Verhulst, Minneapolis, MN (US); Radesh Jewram, Lakeville, MN (US); Reid J. Chesterfield, Eden Prairie, MN (US)

(21) Appl. No.: 17/748,634

(22) Filed: May 19, 2022

Related U.S. Application Data
(63) Continuation of application No. PCT/US2020/061294, filed on Nov. 19, 2020.
(60) Provisional application No. 62/937,498, filed on Nov. 19, 2019.

(51) Int. Cl. C08G 77/08; H05K 7/20

(52) U.S. Cl. CPC C08G 77/08; H05K 7/20481

(57) ABSTRACT

A thermal interface material delivered as a single-component precursor mixture which reacts to form a soft, solid material. Thermally conductive particles are dispersed in the reactive polymer matrix resulting in a composite material with high thermal conductivity. A reaction inhibitor is provided so that the one-component system is stable in storage and handling at room temperature, and curable at an elevated temperature. The uncured precursor material is easily dispensed using conventional single-component automated pumping equipment, and subsequently cured in place.

### FIELD

The present invention related to thermal interface materials generally, and more particularly to mechanically conformable thermally conductive materials that may be formed in place following dispensation from a vessel.

### BACKGROUND

Thermally conductive materials are widely employed as interfaces between, for example, a heat-generating electronic component and a heat dissipater for permitting transfer of excess thermal energy from the electronic component to a thermally coupled heat dissipater. Numerous designs and materials for such thermal interfaces have been implemented, with the highest performance being achieved when air gaps between the thermal interface material and the respective heat transfer surfaces are substantially avoided to promote conductive heat transfer from the electronic component to the heat dissipater. The thermal interface materials therefore preferably mechanically conform to the rough and out of flatness heat transfer surfaces of the respective components.

Example conformable thermal interface materials include silicone polymers forming a matrix that is filled with thermally conductive particles such as aluminum oxide, aluminum nitride and boron nitride. Thermal interface materials are typically sufficiently flexible to conform to irregularities of the interface surfaces, whether at room temperature and/or elevated temperatures. Conventional interface formulations are useful in an array of applications, but nonetheless exhibit limitations in certain situations. For example, some applications are subject to wide temperature cycles and need to withstand mechanical stress and strain throughout the applicable temperature range. Industrial and automotive electronics exposed to outdoor environments require long-term reliability across temperature ranges including between −400° C.-200° C. These conditions, over thousands of hours of lifetime cause conventional interface materials to flow, crack, and slide out of the electronic packages, thereby leading the degradation of electronic device performance.

Thermal interface materials that have been commonly used in such applications are known as “gels”, which are typically non-reactive (pre-cured) silicones with low cross-link density blended with ceramic powered fillers. These materials have good thermal conductivity, but exhibit a low flow rate due to their relatively high viscosity as fully-cured silicones. They also suffer from long-reliability due to the lack of strength, stiffness, and adhesion to substrates in electronic packages.

One attempted solution to the drawbacks of pre-cured silicone gels is a thermally-conductive liquid adhesive which bonds to the substrates in an electronic package. However, use of adhesive materials prevent disassembly for rework during manufacturing. Moreover, adhesive materials generally exhibit relatively high modulus or high hardness values and can accordingly transfer the high level of mechanical stress and strain onto the sensitive electrical components.

Some thermal interface materials are dispended in low-viscosity conditions and subsequently cured into a higher-viscosity state. These form-in-place materials can overcome some of the challenges of other thermal interface material formats, but nevertheless have their own limitations. The form-in-place materials traditionally involve two-component, curable liquid reactant formulations that are dispensed into contact with one another for in situ curing. Two-component solutions require complicated and expensive material handling and dispensing equipment.

It is therefore an object of the present invention to provide a form-in-place material that is dispensable from a single-component dispensing systems currently used in electronics manufacturing. The dispensable material is preferred stable and remains dispensable from the single-component dispensing systems for an extended period of time.

It is another object of the present invention to provide a thermal interface material that is dispensable from a single-component dispensing system and exhibits improved lifetime durability and functionality.

### SUMMARY

By means of the present invention, a mechanically compliant, solid thermal interface material may be formed in place an electronic package and dispended from a single component form factor dispensing system. These dispensing systems are widely available, cost effective, and simple to implement in automated manufacturing processes. The resultant thermal interface material provides an enhanced blend of strength, adhesion, compliance, and durability in comparison to conventional products.

One embodiment of the present invention includes a precursor mixture for forming a thermally conductive material having a thermal conductivity of at least 0.5 W/m*K. The precursor mixture includes a first reactant composition including silicone, and a second reactant composition that is reactive with the first reactant composition to form a siloxane. The precursor mixture further includes a reaction inhibitor that is effective to slow a reaction rate between the first and second reactant compositions at a storage temperature below 40° C. An initial viscosity of the mixture maintained at the storage temperature increases by less than 100% over 14 days.

The second reactant composition may be reactive with the first reactant composition to form a polydimethylsiloxane, which may include a terminal vinyl group, a pendant vinyl group, a terminal silicon hydride, or a pendant silicon hydride. The precursor mixture may also include the reaction catalyst that is inhibited by the reaction inhibitor. Example thermally conductive particles dispersed in at least one of the first and second reactant compositions include aluminum oxide, aluminum nitride, silicon oxide, zinc oxide, and boron nitride.

A package for dispensing a curable mixture to form a thermally conductive body includes a vessel defining a chamber in fluid communication with an office, wherein the curable mixture includes a first reactant composition including silicone, a second reactant composition reactive with the first reactant composition to form a siloxane, a reaction catalyst, a reaction inhibitor, and thermally conductive particles dispersed in at least one of the first and second reactant compositions. The reaction inhibitor is preferable effective to inhibit the catalyzed reaction between the first reactant composition and the second reactant composition at temperatures below 40° C., wherein an initial viscosity of the curable mixture maintained at a storage temperature below 40° C. increases by less than 100% over 14 days. The curable mixture may be dispensable through the orifice at a flow rate of 5-200 g/min under 90 Psi pressure for at least 14 days after initial combination of the curable mixture into the chamber when maintained at the storage temperature of less than 40° C.

A method for applying a thermal interface material to a surface includes providing a curable mixture including a first reactant composition including silicone, a second reactant composition reactive with the first reactant composition to form a siloxane, a reaction catalyst, a reaction inhibitor, and thermally conductive particles dispersed in at least one of the first and second reactant compositions. The reaction inhibitor is effective to interact with the reaction catalyst to slow a reaction rate between the first and second reactant compositions. The method further includes storing the curable mixture in a vessel for more than 24 hours, and dispensing the curable mixture from the vessel through an orifice onto the surface. The surface may be part of a heat generating electronic component.

Some embodiments of the present invention include a method for applying an interface material to a thermal gap between a heat-generating electronic component and a heat dissipation member. The method includes providing a curable mixture having a viscosity of less than 500 Pa*s at 100 s⁻¹ at 25° C., storing the curable mixture in a vessel for more than 24 hours, dispensing the curable mixture from the vessel to a surface of at least one of the heat-generating electronic component and the heat dissipation member, and heating the curable mixture to a temperature above 40° C. for a period of time sufficient to form the thermal interface material from only the curable mixture. The thermal interface material exhibits a durometer hardness of at least Shore 00=5 and a thermal conductivity of at least 0.5 W/m*K.

### BRIEF DESCRIPTION OF THE DRAWINGS

FIG. 1 is a schematic illustration of a precursor mixture being dispensed from a vessel onto a surface.

FIG. 2 is a cross-sectional view of an electronic package incorporating a thermally conductive interface material of the present invention.

FIG. 3 is a chart plotting flow rate of a precursor mixture over time.

FIG. 4 is a chart plotting durometer hardness against mass concentrations of the polymer components of a thermal interface material of the present invention.

### DETAILED DESCRIPTION OF THE PREFERRED EMBODIMENTS

The thermally conductive interface material of the present invention includes a highly conformable silicone polymer filled with thermally conductive particles. Generally, the silicone may be an organosiloxane having the structural formula:

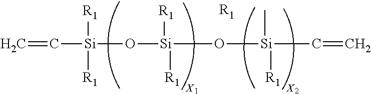

wherein “R₁” represents hydrogen, hydroxyl or methyl groups, and wherein “X₁” and “X₂” represents an integer ranging from between 1 and 1,000 and do not need to be equal. The thermally conductive interface material may be prepared as a reaction product of the organosiloxane together with a chain extender/cross-linker such as a hydride terminated polydimethyl siloxane having the structural formula:

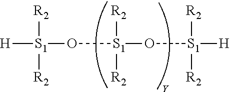

wherein “R₂” represents either hydrogen, methyl or hydroxyl groups, and wherein “Y” represents an integer having a value of between 1 and 1,000.

Generally, the thermally conductive interface material is a curable composition formed from a precursor mixture of a first reactant composition including silicone, a second reactant composition that is reactive with the first reactant composition to from a siloxane, and a reaction catalyst. Organosiloxanes useful in a first reactant composition may include at least two aliphatic unsaturated organic groups such as vinyl, allyl, butenyl, hexenyl, ethenyl, and propenyl. The unsaturated functional groups may be located at terminal or pendant positions.

An example first reactant composition for a curable mixture of the present invention includes polydiorganosiloxanes, such as various vinyl or siloxy-terminated polydimethylsiloxanes (PDMS). Example commercially-available PDMS materials include Nusil PLY-7500, 7905, 7924, and 7925 available from Avantor, Inc.; Evonik VS 100, 200, 500, 10000, 20000, and 65000 available from Evonik Industries AG; and Gelest DMS-V21, V22, V41, V42, and V43 available from Gelest, Inc. The first reactant composition may include one or more polymers that differ in, for example, molecular weight, viscosity, and molecular structure.

The second reactant composition that is reactive with the first reactant composition may include a cross-linker for a hydrosilylation reaction. The second reactant composition may include a dihydroxy aliphatic chain extender such as a hydride-terminated polydimethylsiloxane. The silicon-bonded hydrogen atoms may be located at terminal, pendant, or at both terminal and pendant positions. The second reactant composition may include one or more organohydrogenpolysiloxanes that may differ in at least one of molecular weight, viscosity, and molecular structure. Example commercially-available methylhydropolydimethylsiloxanes useful as a second reactant composition reactive with the first reactant composition include Nusil XL-173, 176, and 177 available from Avantor, Inc.; Gelest HMS-071, 082, and 991 available from Gelest, Inc.; and Andisil XL-1B and 1340 available from AB Specialty Silicones.

In some embodiments, the precursor mixture for forming a thermally conductive material includes a reaction catalyst, such as catalyst effective in a hydrosilylation curable composition. Suitable hydrosilylation catalysts are known in the art and commercially available. Hydrosilylation catalysts may include, for example, platinum, rhodium, palladium, osmium, and complexes and organometallic compounds thereof. Example commercially-available catalysts include Nusil Catalyst 50 from Avantor, Inc.; Gelest SIP6030.3 from Gelest, Inc.; Evonik Catalyst 512 from Evonik Industries AG; and Sigma Aldrich 479519.

In order to enhance the thermal conductivity of the thermally conductive material, the compositions of the present invention may include thermally conductive particles dispersed therein. The particles may be both thermally conductive and electrically conductive. Alternatively, the particles may be thermally conductive and electrically insulating. Example thermally conductive particles include aluminum oxide, silicon oxide, aluminum trihydrate, zinc oxide, graphite, magnesium oxide, aluminum nitride, boron nitride, metal particulate, and combinations thereof. The thermally conductive particles may be of various shape and size, and it is contemplated that a particle size distribution may be employed to fit the parameters of any particular application. In some embodiments, the thermally conductive particles may have an average particle size of between about 0.1-250 micrometers, and may be present in the thermally conductive material at a concentration by weight of between about 20-95%.

The thermally conductive particles may be dispersed in at least one of the first and second reactant compositions at a loading concentration of about between about 20-95% by weight. It is desirable that sufficient thermally conductive particles are provided so that the thermally conductive material formed from the precursor mixture exhibits a thermal conductivity of at least 0.5 W/m*K.

A reaction inhibitor is preferably provided in the precursor mixtures of the present invention that is effective to inhibit the reaction between the first reactant composition and the second reactant composition. An aspect of the present invention is to permit storage of the precursor mixture in a vessel as a single form-factor preparation that is stable at room temperature for at least 14 days. For the purposes hereof, the preparation or precursor mixture that is stable at room temperature is one in which an initial viscosity of the precursor mixture maintained at a storage temperature below 40° C. increases by less than 100% over the course of 14 days. This stability of the precursor mixture permits packaging of the mixture into a vessel and storage for an extended period prior to dispensation. The extended term of stability permits the manufacture and packaging of thermally conductive material to be performed at a place and/or time that is different than the place and/or time of dispensation such as at an electronic package assembler.

In some embodiments, the reaction inhibitor may be effective to interact with the reaction catalyst to slow the reaction rate between the first and second reactant compositions. Generally, the reaction inhibitor may include one or more of a maleate, and acetylenic alcohol, and a fumarate. Example reaction inhibitors include dimethyl maleate, diallyl maleate, bis(1-methoxy-2-propyl)maleate, dibutyl maleate, 1-ethynyl-cyclohexanol, 2-methyl-3-butyn-2-ol, 3,7,11-trimethyl-1-dodecyn-3-ol, 3,5-dimethyl-1-hexyn-3-ol, 1-ethynyl-1-cyclopentanol, 3-methyl-1-dodecyn-3-ol, 4-ethyl-1-octyn-3-ol, 1,1-diphenyl-2-propyn-1-ol, 2,3,6,7-tetramethyl-4-octyne-3,6-diol, 3,6-diethyl-1-nonyn-3-ol, 3-methyl-1-pentadecyn-3-ol, 2,5-dimethyl-3-hexyne-2,5-diol, 2,7-dimethyl-3,5-octadiyne-2,7-diol, 3-methyl-1-pentyn-3-ol, 2,4,7,9-tetramethyl-5-decyne-4,7-diol, 1,4bis(1′-hydroxycyclohexyl)-1,3-butadiyne, 3,4-dimethyl-1-pentyne-3,4-diol, 1-(1-butynyl)cyclopentanol, 2,5-dimethyl-5-hexen-3-yn-2-ol, 5-dimethylamino-2-methyl-3-pentyl-2-ol, 3,6-dimethyl-6-hepten-4-yn-3-ol, 3-methyl-1-octyn-3-ol, 3,4,4-trimethyl-1-pentyn-3-ol, 3-isobutyl-5-methyl-1-hexyn-3-ol, 2,5,8-trimethyl-1-nonen-3-yn-5-ol, 1-(1-propynyl)cyclohexanol.

Various other components are contemplated as being optionally included in the compositions of the present invention, such as adhesion promoters, surfactants, stabilizers, fillers, and combinations thereof.

The precursor mixtures of the present invention are preferably stable at room temperature and will react at elevated temperature, such as above 40° C., to cure to a solid body as a form-in-place interface. The rate of this reaction can be controlled by the concentration of reactive functional groups, the catalyst, and the reaction inhibitor. Rheology of the dispersion may be further controlled by the sizes, shapes, and loading concentration of thermally conductive particles dispersed therein.

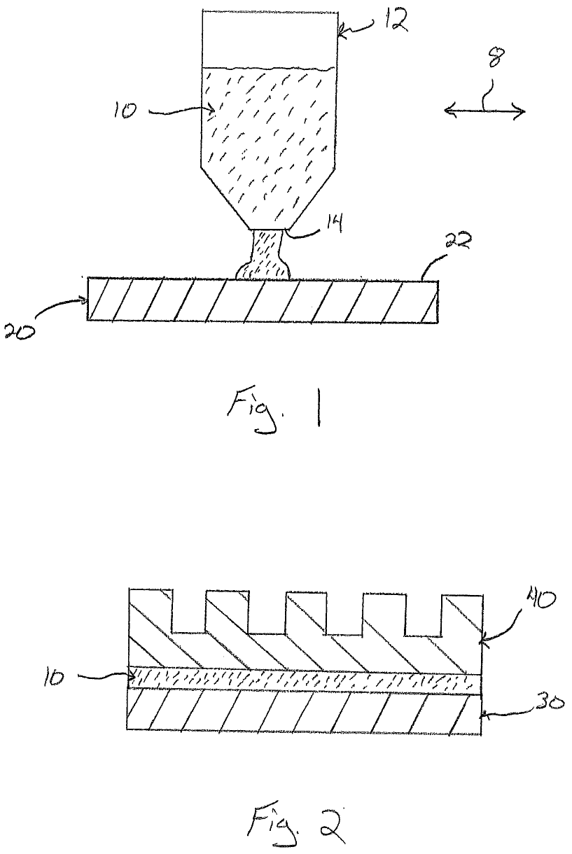

FIG. 1 illustrates an example application of the present invention, wherein a curable mixture 10 is contained in a vessel 12 having an orifice 14 through which the curable mixture may be dispensed. In the illustrated embodiment, curable mixture 10 is dispensed to a surface 22 of a member 20. As is known in the art, one or both of vessel 12 and member 20 may be moved relative to one another, such as along direction arrows 8 to apply the curable mixture 10 as needed at surface 22. Member 20 may, for example, be a heat-generating electronic component or a heat dissipation member. FIG. 2 illustrates curable mixture 10 disposed between the heat-generating electronic component 30 and a heat dissipation member 40. The curable mixture 10 may be heated to above 40° C. for a period of time sufficient to form a thermal interface material from only the curable mixture 10. Heating of the curable mixture in situ may be performed by known heating means, such as a heat oven or the like.

### Examples

An example precursor mixture is sets forth in Table 1 below:

TABLE 1

| Constituent | Concentration (wt %) |
|---|---|
| Vinyl terminated PDMS | 5-15 |
| Methylhydro PDMS | 1-5 |
| Catalyst | <0.1 |
| Dimethyl maleate | <0.1 |
| Aluminum oxide powder | 50-95 |

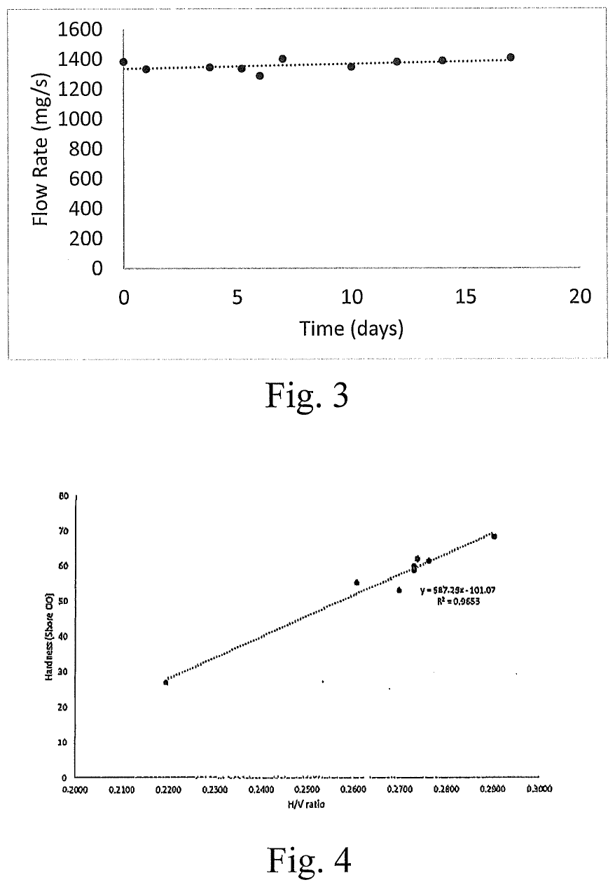

The precursor mixture exhibits an inhibited reaction rate illustrated by the small change in viscosity over an extended working time of at least 14 days with the material at room temperature. FIG. 3 plots a flow rate of the precursor mixture through a 2 mm orifice under 90 Psi pressure at 25° C. over time. This enables automated processing with tight control on dispensed quantity and patterning. The long working time also provides flexibility in the electrical component handling, transportation, and assembly processes.

The final cured thermal interface material exhibits a hardness that is designed to be soft with good adhesion to common metal and plastic substrates found in electronic devices. FIG. 4 illustrates how various hardness levels can be tuned and controlled by the reactivity and concentration of the first and second reactant compositions. Softness of the thermal interface material allows the material to flex and resist cracking as the device goes through thermal cycling during operation. The following Table 2 sets forth physical property parameters of the precursor mixture, as well as hardness for the cured thermally conductive material:

TABLE 2

| Parameter | Range | |
|---|---|---|
| EFD Flow rate - 2 mm orifice, 90 psi | 5-200 | g/min |
| Hardness - Shore 00 | 5-90 | |
| Thermal conductivity - ASTM D5470 | 0.5-5 | W/m-K |
| Low shear viscosity - parallel plate | 100-3500 | Pa*s |
| rheometer, 25 mm platen, 1 mm gap, shear | | |
| rate = 1.0 s⁻¹ | | |
| High shear viscosity - capillary rheometer, | 50-500 | Ps*s |
| 16 × 2 mm die, shear rate = 100 s⁻¹ | | |

The invention has been described herein in considerable detail in order to comply with the patent statutes, and to provide those skilled in the art with the information needed to apply the novel principles and to construct and use embodiments of the invention as required. However, it is to be understood that various modifications can be accomplished without departing from the scope of the invention itself.

What is claimed is:

1. A precursor mixture for forming a thermally conductive material having a thermal conductivity of at least 0.5 W/m*K, said precursor mixture comprising:
a first reactant composition including silicone;
a second reactant composition that is reactive with the first reactant composition to form a siloxane;
a reaction inhibitor effective to slow a reaction rate between the first and second reactant compositions at a storage temperature below 40° C., wherein an initial viscosity of the mixture maintained at the storage temperature increases by less than 100% over 14 days; and
thermally conductive particles dispersed in at least one of the first and second reactant compositions.

2. The precursor mixture as in claim 1 wherein the second reactant composition is reactive with the first reactant composition to form a polydimethylsiloxane.

3. The precursor mixture as in claim 2 wherein the polydimethylsiloxane includes a terminal vinyl group, a pendant vinyl group, a terminal silicon hydride, or a pendant silicon hydride.

4. The precursor mixture as in claim 1, including a reaction catalyst selected from the group consisting of platinum, rhodium, palladium, osmium, and complexes and organometallic compounds thereof.

5. The precursor mixture as in claim 4 wherein the reaction inhibitor includes one or more of a maleate, an acetylenic alcohol, and a fumarate.

6. The precursor mixture as in claim 1 wherein the initial viscosity is less than 500 Pa*s at 100 s⁻¹ at 25° C.

7. The precursor mixture as in claim 1 wherein the initial viscosity is less than 3500 Pa*s at 1.0 s⁻¹ at 25° C.

8. The precursor mixture as in claim 7 being thixotropic.

9. The precursor mixture as in claim 1 wherein the thermally conductive material is curable from the precursor mixture to exhibit a cured durometer of between Shore 00=5 and Shore 00=90 at 25° C.

10. The precursor mixture as in claim 10 wherein the thermally conductive particles include one or more of aluminum oxide, aluminum nitride, silicon oxide, zinc oxide, and boron nitride.

11. A package for dispensing a curable mixture to form a thermally conductive body, said package comprising:
a vessel defining a chamber in fluid communication with an orifice, the curable mixture being disposed in the chamber and including:
a first reactant composition including silicone;
a second reactant composition reactive with the first reactant composition to form a siloxane;
a reaction catalyst;
a reaction inhibitor effective to inhibit the catalyzed reaction between the first reactant composition and the second reactant composition at temperatures below 40° C., wherein an initial viscosity of the curable mixture maintained at a storage temperature below 40° C. increases by less than 100% over 14 days; and
thermally conductive particles dispersed in at least one of the first and second reactant compositions;

12. The package as in claim 11 wherein the thermally conductive body exhibits a thermal conductivity of at least 0.5 W/m*K.

13. The package as in claim 12 wherein initial viscosity is between 100-3,500 Pa*s at 1.0 s⁻¹ at 25° C.

14. The package as in claim 13 wherein the initial viscosity is between 50-500 Pa*s and 100 s⁻¹ at 25° C.

15. The package as in claim 14 wherein the curable mixture is curable to a durometer hardness of between Shore 00=5 and Shore 00=90.

16. The package as in claim 11 wherein the curable mixture is dispensable through the orifice at a flow rate of 5-200 g/min under 90 Psi pressure for at least 14 days after initial combination of the curable mixture into the chamber when maintained at the storage temperature of less than 40° C.

17. The package as in claim 16 wherein the orifice is 2 mm or less in diameter.

18. A method for applying a thermal interface material to a surface, said method comprising:
(a) providing a curable mixture including:
(i) a first reactant composition including silicone;
(ii) a second reactant composition reactive with the first reactant composition to form a siloxane;
(iii) a reaction catalyst
(iv) a reaction inhibitor effective to interact with the reaction catalyst to slow a reaction rate between the first and second reactant compositions; and
(v) thermally conductive particles dispersed in at least one of the first and second reactant compositions;
(b) storing the curable mixture in a vessel for more than 24 hours; and
(c) dispensing the curable mixture from the vessel through an orifice onto the surface.

19. The method as in claim 18, including, subsequent to dispensing, heating the curable mixture to above 40° C. for a period of time sufficient to cure the curable mixture.

20. The method as in claim 18 wherein the thermal interface material exhibits a thermal conductivity of at least 0.5 W/m*K.

21. The method as in claim 18 wherein the surface is part of a heat-generating electronic component.

22. The method as in claim 21, including dispensing the curable mixture between the surface and a heat dissipation member.

23. The method as in claim 18 wherein the orifice is 2 mm or less in diameter.

24. A method for applying a thermal interface material to a surface for filling a thermal gap between a heat-generating electronic component and a heat dissipation member, said method comprising:
(a) providing a curable mixture having a viscosity of less than 500 Pa*s at 100 s⁻¹ at 25° C.;
(b) storing the curable mixture in a vessel for more than 24 hours;
(c) dispensing the curable mixture from the vessel to the surface of at least one of the heat-generating electronic component and the heat dissipation member; and
(d) heating the curable mixture to above 40° C. for a period of time sufficient to form the thermal interface material from only the curable mixture,
wherein said thermal interface material exhibits a durometer hardness of at least 5 shore 00 and a thermal conductivity of at least 0.5 W/m*K.

25. The method as in claim 24 wherein said thermal interface material includes a siloxane.

26. The method as in claim 25 wherein the siloxane includes a polydimethylsiloxane with a terminal vinyl group, a pendant vinyl group, a terminal silicon hydroxide, or a pendant silicon hydride.

27. The method as in claim 24, including storing the curable mixture in the vessel at less than 40° C.

28. The method as in claim 24, including sandwiching the thermal interface material between the heat-generating electronic component and the heat dissipation member.

29. The method as in claim 28 wherein the thermal interface material is in physical contact with each of said heat-generating electronic component and said heat dissipation member.
